(19) United States
(12) Patent Application Publication
(10) Pub. No.: US 2006/0289999 A1
(43) Pub. Date: Dec. 28, 2006

(54) Selective copper alloy interconnections in semiconductor devices and methods of forming the same

(75) Inventors: Hyo-Jong Lee, Seoul (KR); Sun-Jung Lee, Seoul (KR); Bong-Seok Suh, Gyeonggi-do (KR); Hong-Jae Shin, Seoul (KR); Nae-In Lee, Seoul (KR); Kyoung-Woo Lee, Seoul (KR); Se-Young Jeong, Seoul (KR); Jeong-Hoon Ahn, Gyeonggi-do (KR); Soo-Geun Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/389,868

(22) Filed: Mar. 27, 2006

(30) Foreign Application Priority Data
Jun. 22, 2005 (KR) 10-2005-0054167

(51) Int. Cl. H01L 23/48

(52) U.S. Cl. 257/762

(57) ABSTRACT

A selective copper alloy interconnection in a semiconductor device is provided. The interconnection includes a substrate, a dielectric formed on the substrate, and a first interconnection formed in the dielectric. The first interconnection has a first pure copper pattern. In addition, a second interconnection having a larger width than the first interconnection is formed in the dielectric. The second interconnection has a copper alloy pattern. The copper alloy pattern may be an alloy layer formed of copper (Cu) and an additive material. A method of forming the selective copper alloy pattern is also provided.

### CROSS-REFERENCE TO RELATED APPLICATION

This application claims the benefit of Korean Patent Application No. 2005-0054167, filed Jun. 22, 2005, the contents of which are hereby incorporated herein by reference in their entirety.

### FIELD OF THE INVENTION

The present invention relates generally to semiconductor devices and methods of fabricating the same, and more particularly, to selective copper alloy interconnections of semiconductor devices and methods of forming the same.

### BACKGROUND OF THE INVENTION

As semiconductor devices become highly integrated, interconnections having lower resistance and higher reliability are required. Accordingly, research on methods of using copper (Cu) as an interconnection material of semiconductor devices has been conducted. Copper has a lower resistivity than aluminum (Al) which is a conventional interconnection material. In addition, copper has a relatively high melting point compared to aluminum. Moreover, copper has a much higher resistance to electromigration (EM) than aluminum.

FIG. 1 is a perspective view showing a part of a conventional semiconductor device employing copper as an interconnection material.

Referring to FIG. 1, the illustrated semiconductor device includes a lower conductive pattern 11 formed in a predetermined region of a substrate (not shown). An upper copper interconnection 15 is disposed over the lower conductive pattern 11 to be spaced apart from the lower conductive pattern 11. An inter-level dielectric (not shown) is interposed between the lower conductive pattern 11 and the upper copper interconnection 15. The lower conductive pattern 11 and the upper copper interconnection 15 are connected by a contact plug 13 penetrating the inter-level dielectric. The upper copper interconnection 15 and the contact plug 13 are formed of copper.

The semiconductor device then suffers from stress in a subsequent process such as an annealing process. As shown in FIG. 1, when the upper copper interconnection 15 has a large line width, a stress gradient is formed at a lower region V of the contact plug 13. That is, the stress is concentrated on the lower region V. The stress gradient causes vacancies and small voids within the upper copper interconnection 15 to move toward the lower region V of the contact plug 13 via grain boundaries. As a result, a stress induced void (SIV) is formed at the lower region V of the contact plug 13. The SIV degrades current drivability of the contact plug 13. That is, the SIV causes electrical failures between the lower conductive pattern 11 and the upper copper interconnection 15. In addition, the upper copper interconnection 15 formed of copper causes hillocks to form on the grain boundaries. It has been known that relatively large hillocks are formed when the upper copper interconnection 15 has a large line width.

A method of forming a copper alloy interconnection has been tried to suppress defects such as the SIV and hillocks from being formed. It has been reported that the copper alloy interconnection has a higher resistivity and a better reliability than a pure copper interconnection.

FIGS. 2 to 4 are cross-sectional views illustrating a method of forming a conventional copper alloy interconnection.

Referring to FIG. 2, a lower inter-level dielectric 23 is formed on a semiconductor substrate 21. A lower conductive pattern 25 is formed in the lower inter-level dielectric 23. The lower conductive pattern 25 is formed of a conductive material layer such as a metal layer or a semiconductor layer. An upper inter-level dielectric 27 is formed on the semiconductor substrate 21 having the lower conductive pattern 25. A wide trench 33 and a narrow trench 35 are formed in the upper inter-level dielectric 27. The wide trench 33 has a larger width than the narrow trench 35. A contact hole 31, which penetrates the upper inter-level dielectric 27 to expose the lower conductive pattern 25, is formed in the wide trench 33.

A barrier metal layer 37 is formed to conformally cover inner walls of the narrow trench 35, the wide trench 33, and the contact hole 31. A copper layer 38 is formed on the semiconductor substrate 21 having the barrier metal layer 37. The copper layer 38 fills the narrow trench 35, the wide trench 33, and the contact hole 31, and covers a top surface of the semiconductor substrate 21. An aluminum layer 39 is formed on the copper layer 38.

Referring to FIG. 3, the copper layer 38 and the aluminum layer 39 are annealed to form a copper-aluminum alloy layer 40. As a result, the barrier metal layer 37 and the copper-aluminum alloy layer 40, which are sequentially stacked, are filled within the narrow trench 35, the wide trench 33, and the contact hole 31.

Referring to FIG. 4, the copper-aluminum alloy layer 40 and the barrier metal layer 37 are planarized to form a narrow interconnection 45 and a wide interconnection 43 at the same time. The narrow interconnection 45 is formed within the narrow trench 35, and the wide interconnection 43 is formed within the wide trench 33. While the wide interconnection 43 is formed, the copper-aluminum alloy layer 40 remains within the contact hole 31. The copper-aluminum alloy layer 40 remaining in the contact hole 31 acts as a contact plug. In addition, bottom surfaces and sidewalls of the narrow interconnection 45 and the wide interconnection 43 are surrounded by a barrier metal pattern 37′.

According to the method of forming the conventional copper alloy interconnection as described above, both the narrow interconnection 45 and the wide interconnection 43 are formed of the copper-aluminum alloy layer 40. It is known that the copper-aluminum alloy layer 40 has excellent reliability. For example, a copper-aluminum alloy interconnection having a composition ratio of Cu-0.3% Al has an EM life time ten times as long as a pure copper interconnection. That is, the copper-aluminum alloy interconnection has superior EM characteristics compared to the pure copper interconnection. However, the copper-aluminum alloy layer 40 has a relatively high resistivity. It has been reported that resistance increase rate of the copper-aluminum alloy layer 40 is 2μΩ.cm/at % Al.

In general, when the resistivity of the interconnection increases, a RC delay relatively increases. In addition, the RC delay due to the increase in resistivity is relatively sensitive in the narrow interconnection 45 compared to the wide interconnection 43. That is, the increase in resistivity causes the RC delay of the narrow interconnection 45 to increase. The RC delay causes the operating speed of the semiconductor device to decrease.

Consequently, a technique capable of preventing the resistivity of the narrow interconnection 45 from increasing is desirable.

A technique associated with copper alloy interconnections is disclosed in 2003 Symposium on VLSI Technology Digest pp. 127-128, entitled “Thermally robust 90 nm node CU—Al wiring technology using solid phase reaction between Cu and Al” to Y Matsubara et al. Matsubara et al. describes a technique capable of improving the SIV and EM characteristics. However, the Matsubara et al. technique may not prevent the resistance increase in narrow interconnections and may not enhance the reliability of wide interconnections.

### SUMMARY OF THE INVENTION

An embodiment of the invention provides a selective copper alloy interconnection in a semiconductor device which is capable of enhancing reliability of a wide interconnection while preventing a resistance increase in a narrow interconnection.

Another embodiment of the present invention provides a method of forming an interconnection in a semiconductor device which is capable of enhancing reliability of a wide interconnection while preventing a resistance increase in a narrow interconnection.

In one embodiment, the invention is directed to a selective copper alloy interconnection in a semiconductor device. The interconnection includes a substrate, a dielectric formed on the substrate, and a first interconnection formed in the dielectric. The first interconnection has a first pure copper pattern. In addition, a second interconnection having a larger width than the first interconnection is formed in the dielectric. The second interconnection has a copper alloy pattern.

In some embodiments of the present invention, the copper alloy pattern may be an alloy layer formed of copper (Cu) and an additive material. The additive material may be at least one selected from the group consisting of aluminum (Al), tin (Sn), lead (Pb), zinc (Zn), platinum (Pt), palladium (Pd), nickel (Ni), silver (Ag), gold (Au), indium (In), magnesium (Mg), a copper-aluminum (Cu—Al) alloy, and a copper-tin (Cu—Sn) alloy.

In another embodiment, the invention is directed to a selective copper alloy interconnection in a semiconductor device. The interconnection includes a substrate, a dielectric formed on the substrate, and a first interconnection formed in the dielectric. The first interconnection has a first pure copper pattern. In addition, a second interconnection having a larger width than the first interconnection is formed in the dielectric. The second interconnection has a copper alloy pattern. In addition, a lower conductive pattern is formed below the second interconnection and spaced apart from the second interconnection. A contact plug penetrating the dielectric is formed between the lower conductive pattern and the second interconnection. One end of the contact plug is in contact with the lower conductive pattern and the other end of the contact plug is in contact with the second interconnection.

In another embodiment, the invention is directed to a method of forming an interconnection in a semiconductor device. The method includes forming a dielectric on a substrate, and forming a first trench and a second trench in the dielectric. The second trench has a larger width than the first trench. A first interconnection and a second interconnection are formed in the first trench and the second trench, respectively. The first interconnection has a first pure copper pattern, and the second interconnection has a copper alloy pattern.

### BRIEF DESCRIPTION OF THE DRAWINGS

The foregoing and other objects, features and advantages of the invention will be apparent from the more particular description of embodiments of the invention, as illustrated in the accompanying drawings. The drawings are not necessarily to scale, emphasis instead being placed upon illustrating the principles of the invention.

FIG. 1 is a perspective view showing a part of a conventional semiconductor device employing copper as an interconnection material.

FIGS. 2 to 4 are cross-sectional views illustrating a method of forming a conventional copper alloy interconnection.

FIGS. 5 to 11 are cross-sectional views illustrating a method of fabricating a semiconductor device having a selective copper alloy interconnection in accordance with some embodiments of the present invention.

FIGS. 12 to 15 are cross-sectional views illustrating a method of fabricating a semiconductor device having a selective copper alloy interconnection in accordance with some embodiments of the present invention.

FIGS. 16 to 19 are cross-sectional views illustrating a method of fabricating a semiconductor device having a selective copper alloy interconnection in accordance with some embodiments of the present invention.

FIGS. 20 and 21 are characteristic diagrams showing sheet resistances of a selective copper alloy interconnection fabricated in accordance with some embodiments of the present invention.

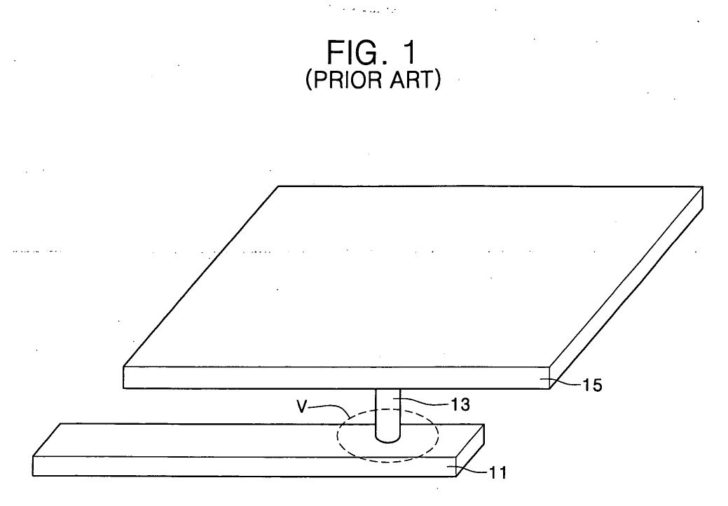

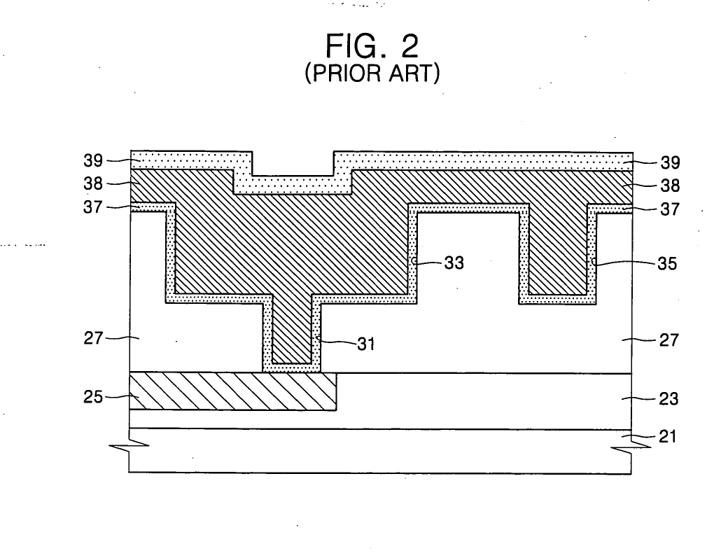

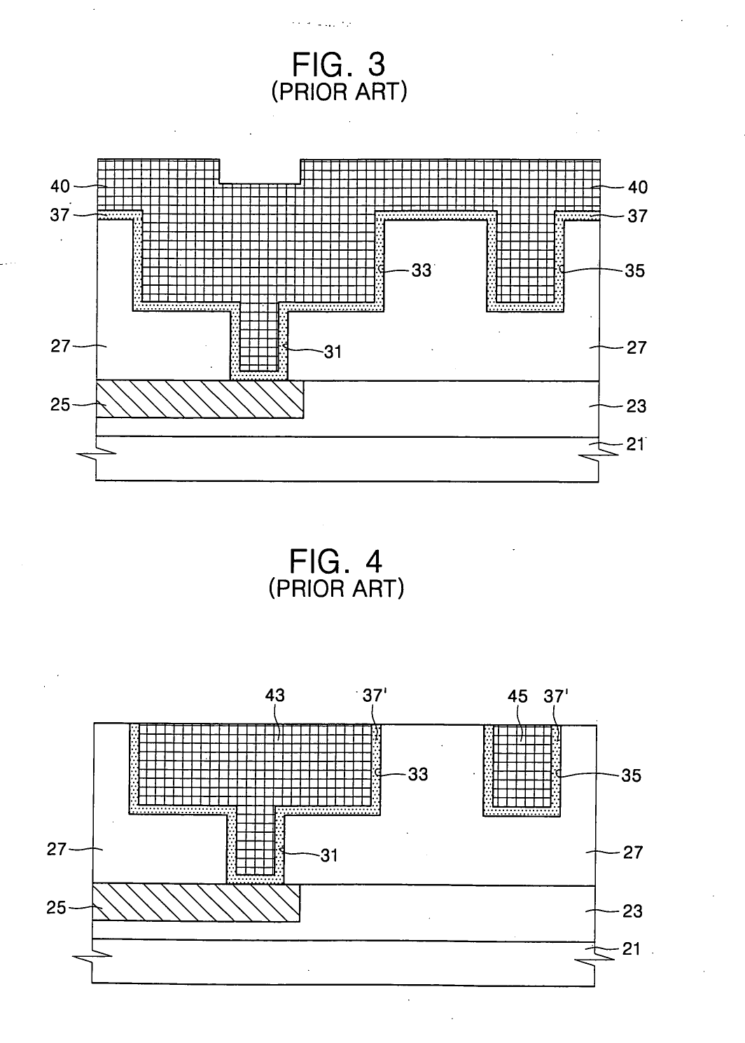

### DETAILED DESCRIPTION OF THE INVENTION

The present invention will now be described more fully hereinafter with reference to the accompanying drawings, in which some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. In addition, when a layer is described to be formed on another layer or on a substrate, this means that the layer may be formed on the other layer or on the substrate, or a third layer may be interposed between the layer and the other layer or the substrate. Like numbers refer to like elements throughout the specification.

All publications, patent applications, patents, and other references mentioned herein are incorporated herein by reference in their entireties.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y As used herein, phrases such as “between about X and Y” mean “between about X and about Y.” As used herein, phrases such as “from about X to Y” mean “from about X to about Y.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of “over” and “under”. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a “first” element, component, region, layer or section discussed below could also be termed a “second” element, component, region, layer or section without departing from the teachings of the present invention. The sequence of operations (or steps) is not limited to the order presented in the claims or figures unless specifically indicated otherwise.

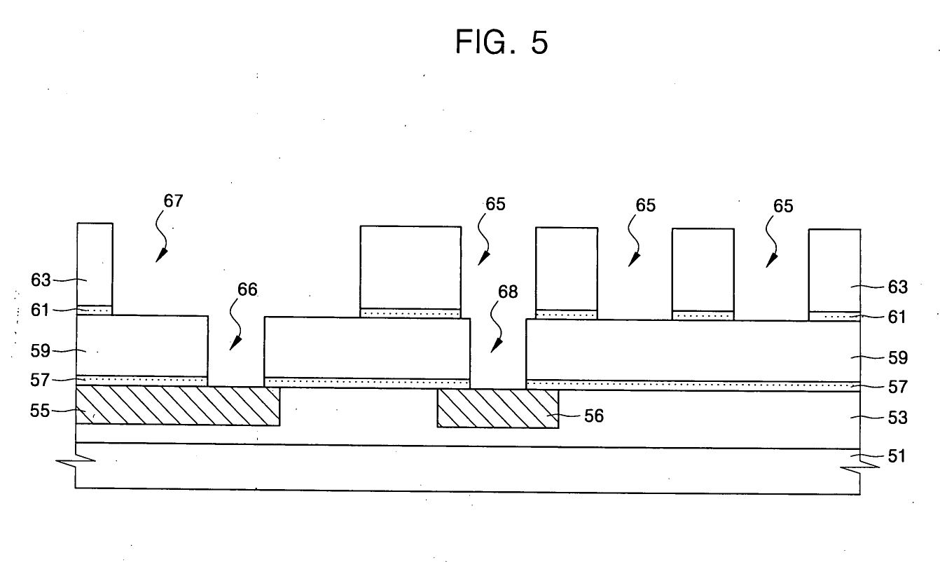

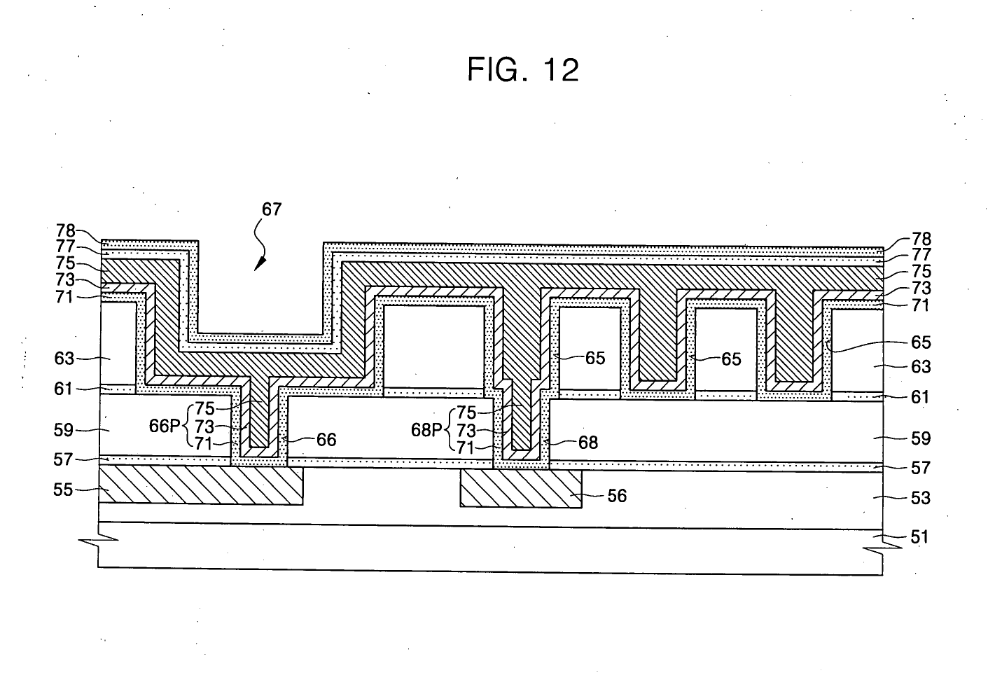

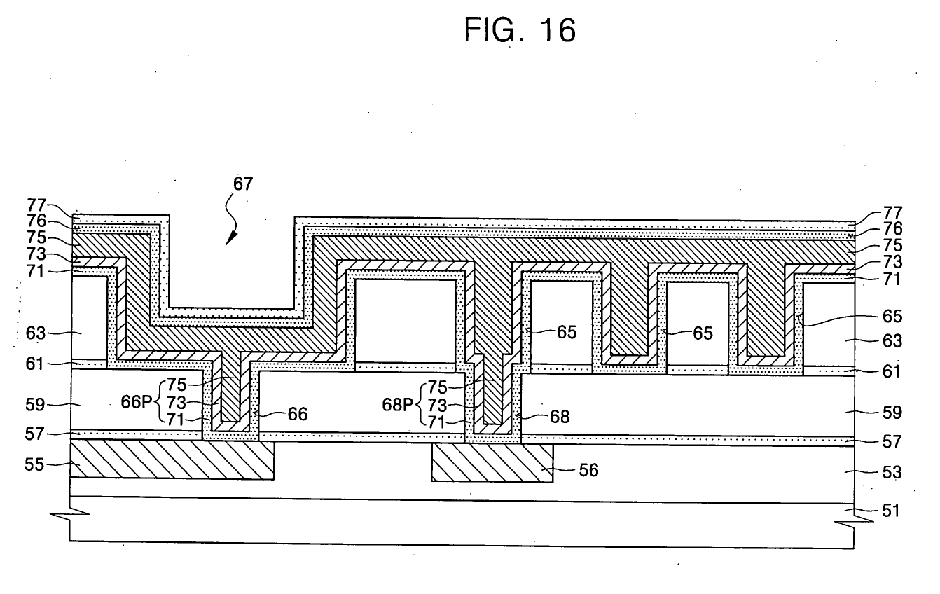

FIGS. 5 to 11 are cross-sectional views illustrating a method of fabricating a semiconductor device having a selective copper alloy interconnection in accordance with some embodiments of the present invention, and FIGS. 12 to 15 are cross-sectional views illustrating a method of fabricating a semiconductor device having a selective copper alloy interconnection in accordance with some embodiments of the present invention. In addition, FIGS. 16 to 19 are cross-sectional views illustrating a method of fabricating a semiconductor device having a selective copper alloy interconnection in accordance with some embodiments of the present invention.

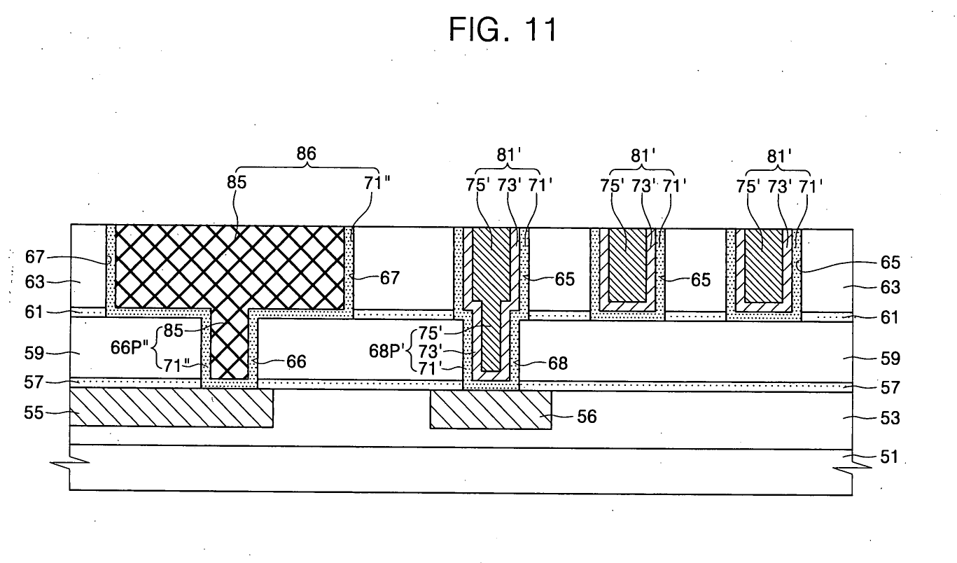

First, a semiconductor device having a selective copper alloy interconnection according to some embodiments of the present invention will be described with reference to FIG. 11.

Referring to FIG. 11, the illustrated semiconductor device includes a substrate 51, dielectrics 53, 57, 59, 61, and 63, first trenches 65, and a second trench 67.

The substrate 51 may be a semiconductor substrate such as a silicon wafer. Components such as a transistor may be disposed on the substrate 51, however, they will be omitted for simplicity of description. The dielectrics 53, 57, 59, 61, and 63 may be a lower inter-level dielectric 53, a lower etch stop layer 57, an intermediate inter-level dielectric 59, an upper etch stop layer 61, and an upper inter-level dielectric 63 which are sequentially stacked, respectively. However, the lower etch stop layer 57 and the upper etch stop layer 61 may be omitted. The dielectrics 53, 57, 59, 61, and 63 are stacked on the substrate 51. A first lower conductive pattern 55 and another second lower conductive pattern 56 may be disposed within the lower inter-level dielectric 53. The lower conductive patterns 55 and 56 may be spaced apart from each other. The lower conductive patterns 55 and 56 may be semiconductor layers such as a metal layer, a metal silicide layer and a polysilicon layer, or combination layers thereof.

The upper inter-level dielectric 63 preferably has a planarized top surface. The first trenches 65 and the second trench 67 may be formed within the upper etch stop layer 61 and the upper inter-level dielectric 63. The second trench 67 may have a larger width than the first trenches 65. Depths of the trenches 65 and 67 may be in a range of about 100 nm to 5000 nm.

A contact hole 66 may be formed below the second trench 67. The contact hole 66 may sequentially penetrate the intermediate inter-level dielectric 59 and the lower etch stop layer 57 to expose the lower conductive pattern 55. Another contact hole 68 may be formed also on a bottom surface of the first trench 65. The other contact hole 68 may sequentially penetrate the intermediate inter-level dielectric 59 and the lower etch stop layer 57 to expose the other lower conductive pattern 56. Depths of the contact holes 66 and 68 may be in a range of about 100 nm to 1500 nm.

First interconnections 81′ are formed within the first trenches 65. Each of the first interconnections 81′ has a first pure copper pattern 75′. In addition, each of the first interconnections 81′ may have a first barrier metal pattern 71′, a first lower seed pattern 73′, and the first pure copper pattern 75′ which are sequentially stacked. The first pure copper pattern 75′ may be a copper (Cu) layer. The first lower seed pattern 73′ may be formed of one selected from the group consisting of Cu, Pt, Pd, Ni, Ag and Au, or an alloy layer thereof. Alternatively, the first lower seed pattern 73′ may be omitted.

A second interconnection 86 is formed within the second trench 67. The second interconnection 86 includes a copper alloy pattern 85. Sidewalls and a bottom surface of the copper alloy pattern 85 may be surrounded by a second barrier metal pattern 71″. The copper alloy pattern 85 may be an alloy layer formed of Cu and an additive material. The additive material may be at least one selected from the group consisting of Al, Sn, Pb, Zn, Pt, Pd, Ni, Ag, Au, In, Mg, a Cu—Al alloy, and a Cu—Sn alloy.

A copper alloy plug 66P″ may be formed within the contact hole 66. The copper alloy plug 66P″ may have the second barrier metal pattern 71″ and the copper alloy pattern 85 which are sequentially stacked. The copper alloy plug 66P″ may act to electrically connect the second interconnection 86 to the lower conductive pattern 55. Another contact plug 68P′ may be formed within the other contact hole 68. The other contact plug 68P′ may have the first barrier metal pattern 71′, the first lower seed pattern 73′, and the first pure copper pattern 75′ which are sequentially stacked. Alternatively, the first lower seed pattern 73′ may be omitted. The other contact plug 68P′ may act to electrically connect the first interconnection 81′ to the other lower conductive pattern 56.

The first and second barrier metal patterns 71′ and 71″ may be formed of one selected from the group consisting of tantalum (Ta), tantalum nitride (TaN), titanium (Ti), titanium nitride (TiN), titanium silicon nitride (TiSiN) and tungsten nitride (WN), or a combination layer thereof.

Top surfaces of the upper inter-level dielectric 63, the first interconnections 81′ and the second interconnection 86 may be formed substantially on the same plane.

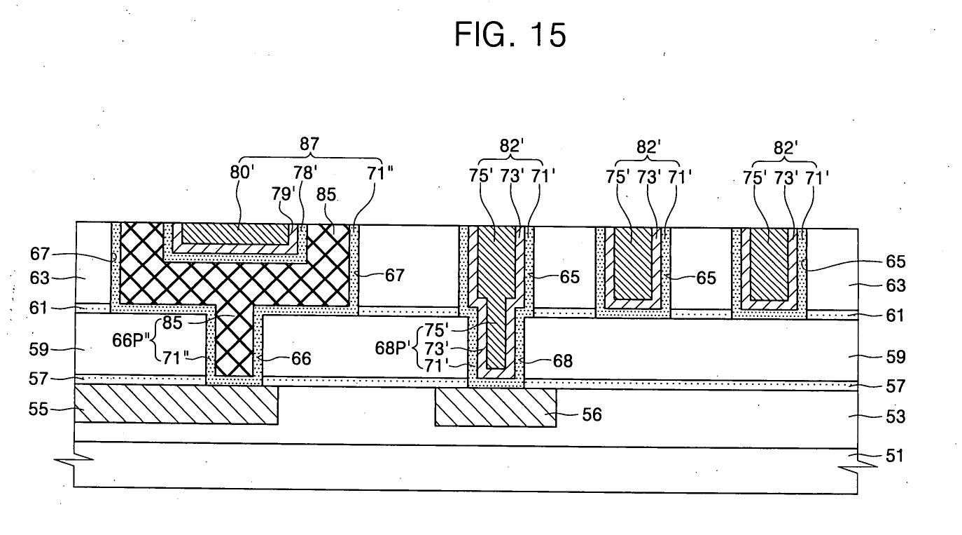

Hereinafter, a semiconductor device having a selective copper alloy interconnection according to other embodiments of the present invention will be described with reference to FIG. 15.

Referring to FIG. 15, a substrate 51, dielectrics 53, 57, 59, 61, and 63, first trenches 65, and a second trench 67 are provided which have the same structure as that described with reference to FIG. 11. Hereinafter, a difference therebetween will be described in brief.

First interconnections 82′ are formed within the first trenches 65. Each of the first interconnections 82′ has a first pure copper pattern 75′. In addition, each of the first interconnections 82′ may have a first barrier metal pattern 71′, a first lower seed pattern 73′, and the first pure copper pattern 75′ which are sequentially stacked. The first pure copper pattern 75′ may be a copper layer.

A second interconnection 87 is formed within the second trench 67. The second interconnection 87 has a copper alloy pattern 85. In addition, the second interconnection 87 may have a second barrier metal pattern 71″, a copper alloy pattern 85, an upper barrier metal pattern 78′, an upper seed pattern 79′, and an upper pure copper pattern 80′ which are sequentially stacked. A bottom surface of the upper barrier metal pattern 78′ may be lower than a top surface of the upper inter-level dielectric 63. The copper alloy pattern 85 may be an alloy layer formed of Cu and an additive material. The upper barrier metal pattern 78′ may be formed of one selected from the group consisting of Ta, TaN, Ti, TiN, TiSiN and WN, or a combination layer thereof. The upper seed pattern 79′ may be formed of one selected from the group consisting of Cu, Pt, Pd, Ni, Ag and Au, or an alloy layer thereof. Alternatively, the upper seed pattern 79′ may be omitted.

A copper alloy plug 66P″ may be formed within the contact hole 66. The copper alloy plug 66P″ may have the second barrier metal pattern 71″ and the copper alloy pattern 85 which are sequentially stacked. The copper alloy plug 66P″ may act to electrically connect the second interconnection 87 to the first lower conductive pattern 55. Another contact plug 68P′ may be formed within the other contact hole 68. The other contact plug 68P′ may have the first barrier metal pattern 71′, the first lower seed pattern 73′, and the first pure copper pattern 75′ which are sequentially stacked.

Top surfaces of the upper inter-level dielectric 63, the first interconnections 82′ and the second interconnection 87 may be formed substantially on the same plane.

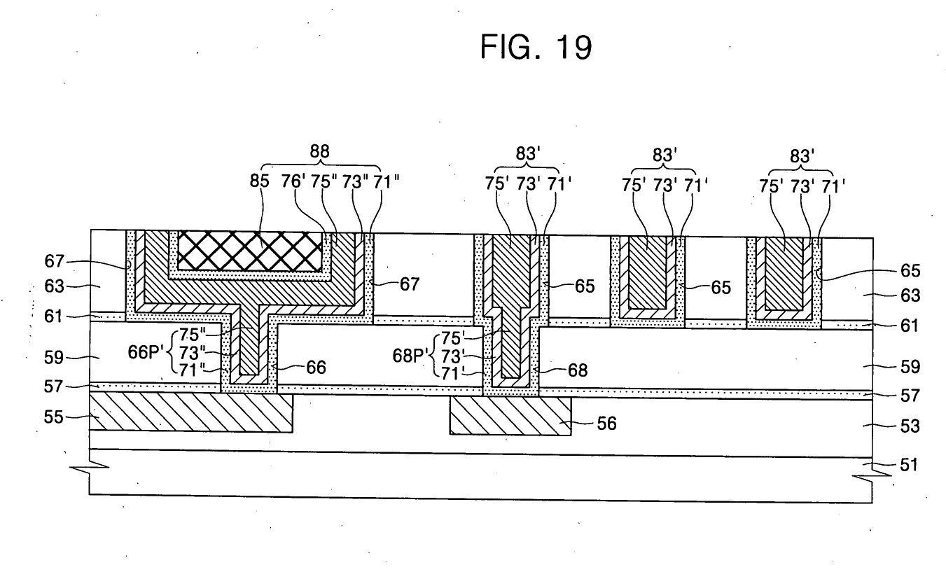

Hereinafter, a semiconductor device having a selective copper alloy interconnection according to other embodiments of the present invention will be described with reference to FIG. 19.

Referring to FIG. 19, a substrate 51, dielectrics 53, 57, 59, 61, and 63, first trenches 65, and a second trench 67 are provided which have the same structure as that described with reference to FIG. 11. Hereinafter, a difference therebetween will be described in brief.

First interconnections 83′ are formed within the first trenches 65. Each of the first interconnections 83′ has a first pure copper pattern 75′. In addition, each of the first interconnections 83′ may have a first barrier metal pattern 71′, a first lower seed pattern 73′, and the first pure copper pattern 75′ which are sequentially stacked. The first pure copper pattern 75′ may be a copper layer.

A second interconnection 88 is formed within the second trench 67. The second interconnection 88 has a copper alloy pattern 85. In addition, the second interconnection 88 may have a second barrier metal pattern 71″, a second lower seed pattern 73″, a second pure copper pattern 75″, an intermediate barrier metal pattern 76′, and a copper alloy pattern 85 which are sequentially stacked. A bottom surface of the intermediate barrier metal pattern 76′ may be lower than a top surface of the upper inter-level dielectric 63. In addition, a bottom surface of the copper alloy pattern 85 may be lower than a top surface of the upper inter-level dielectric 63. The copper alloy pattern 85 may be an alloy layer formed of Cu and an additive material.

The intermediate barrier metal pattern 76′ may be formed of one selected from the group consisting of Ta, TaN, Ti, TiN, TiSiN and WN, or a combination layer thereof. The second lower seed pattern 73″ may be formed of one selected from the group consisting of Cu, Pt, Pd, Ni, Ag and Au, or an alloy layer thereof. Alternatively, the second lower seed pattern 73″ may be omitted.

A contact plug 66P′ may be formed within the contact hole 66. The contact plug 66P′ may have the second barrier metal pattern 71″, the second lower seed pattern 73″, and the second pure copper pattern 75″ which are sequentially stacked. The contact plug 66P′ may act to electrically connect the second interconnection 88 to the lower conductive pattern 55. Another contact plug 68P′ may be formed within the other contact hole 68. The other contact plug 68P′ may have the first barrier metal pattern 71′, the first lower seed pattern 73′, and the first pure copper pattern 75′ which are sequentially stacked.

Top surfaces of the upper inter-level dielectric 63, the first interconnections 83′ and the second interconnection 88 may be formed substantially on the same plane.

Hereinafter, a method of forming a semiconductor device having a selective copper alloy interconnection according to exemplary embodiments of the present invention will be described with reference to FIGS. 5 to 11.

Referring to FIG. 5, a method of forming the semiconductor device according to some embodiments of the present invention includes forming dielectrics 53, 57, 59, 61, and 63, first trenches 65, and a second trench 67 on a substrate 51.

To detail this, the substrate 51 may be a semiconductor substrate such as a silicon wafer. Components such as a transistor may be disposed on the substrate 51, however, they will be omitted for simplicity of description. A lower inter-level dielectric 53 is formed on the substrate 51. The lower inter-level dielectric 53 may be formed of a dielectric such as a silicon oxide layer. A first lower conductive pattern 55 and another second lower conductive pattern 56 are formed within the lower inter-level dielectric 53. The lower conductive patterns 55 and 56 may be spaced apart from each other. The lower conductive patterns 55 and 56 may be semiconductor layers such as a metal layer, a metal silicide layer and a polysilicon layer, or combination layers thereof. A lower etch stop layer 57 may be formed on the lower inter-level dielectric 53 having the lower conductive patterns 55 and 56. An intermediate inter-level dielectric 59 may be formed on the substrate 51 having the lower etch stop layer 57. The intermediate inter-level dielectric 59 may act as an inter-metal dielectric. The intermediate inter-level dielectric 59 may be formed of a dielectric such as a silicon oxide layer. The lower etch stop layer 57 is preferably formed of a material layer having an etch selectivity with respect to the intermediate inter-level dielectric 59. For example, the lower etch stop layer 57 may be formed of a silicon nitride layer. An upper etch stop layer 61 may be formed on the intermediate inter-level dielectric 59. An upper inter-level dielectric 63 is formed on the substrate 51 having the upper etch stop layer 61. The upper inter-level dielectric 63 may also act as an inter-metal dielectric. The upper inter-level dielectric 63 may be formed of a dielectric such as a silicon oxide layer. The upper etch stop layer 61 is preferably formed of a material layer having an etch selectivity with respect to the upper inter-level dielectric 63. For example, the upper etch stop layer 61 may be formed of a silicon nitride layer. A top surface of the upper inter-level dielectric 63 is preferably planarized. A chemical mechanical polishing (CMP) or etch-back process may be applied to the planarization of the upper inter-level dielectric 63.

The upper inter-level dielectric 63 is patterned to form the first trenches 65 and the second trench 67. The second trench 67 may have a larger width than the first trenches 65. For example, the second trench 67 may have a width of 1.0 um. As a result, the upper etch stop layer 61 may be exposed on bottom surfaces of the first and second trenches 65 and 67. The exposed upper etch stop layer 61 and the intermediate inter-level dielectric 59 may be continuously patterned to form a contact hole 66 below the second trench 67. The lower etch stop layer 57 may be exposed on a bottom surface of the contact hole 66. While the contact hole 66 is formed, another contact hole 68 may be formed on the bottom surface of the first trench 65. The lower etch stop layer 57 may also be exposed on a bottom surface of the other contact hole 68. Subsequently, the etch stop layers 57 and 61 exposed in the trenches 65 and 67 and the contact holes 66 and 68 are removed. For example, when the etch stop layers 57 and 61 are silicon nitride layers, a process of removing the etch stop layers 57 and 61 may use a cleaning solution containing phosphoric acid. In addition, a dry etch process may be employed to remove the etch stop layers 57 and 61. As a result, the intermediate inter-level dielectric 59 may be exposed on the bottom surfaces of the first and second trenches 65 and 67. In addition, the lower conductive pattern 55 may be exposed on the bottom surface of the contact hole 66, and the lower conductive pattern 56 may also be exposed on the bottom surface of the other contact hole 68.

Alternatively, the upper inter-level dielectric 63, the upper etch stop layer 61, and the intermediate inter-level dielectric 59 may be continuously patterned to form the contact holes 66 and 68. The lower etch stop layer 57 may be exposed on the bottom surfaces of the contact holes 66 and 68. Subsequently, the upper inter-level dielectric 63 may be patterned to form the first trenches 65 and the second trench 67. The upper etch stop layer 61 may be exposed on the bottom surface of the trenches 65 and 67. The exposed upper and lower etch stop layers 61 and 57 are removed. As a result, the trenches 65 and 67 and the contact holes 66 and 68 may be formed.

The trenches 65 and 67 may have depths of about 100 nm to 5000 nm. The contact holes 66 and 68 may have depths of about 100 nm to 1500 nm.

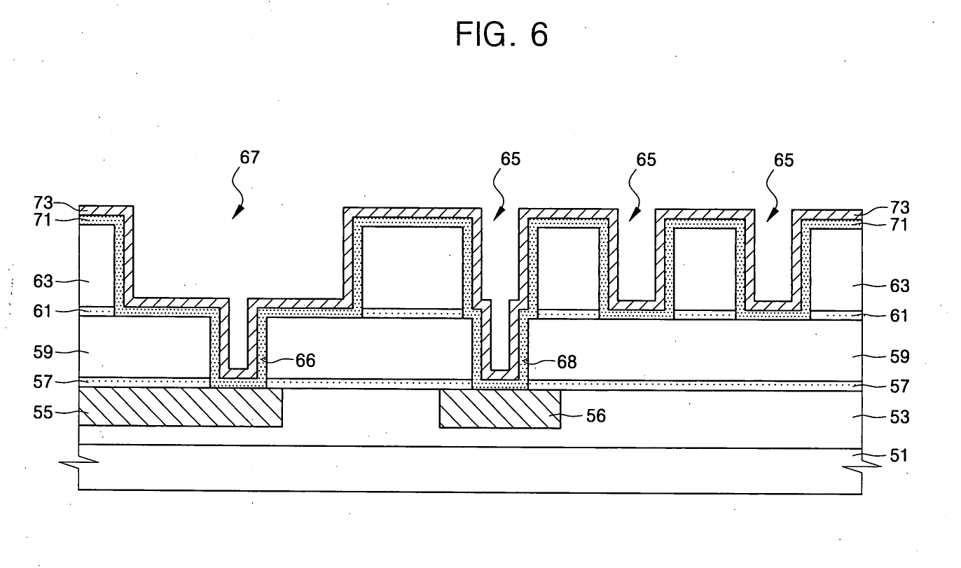

Referring to FIG. 6, a barrier metal layer 71 may be formed on the substrate 51 having the trenches 65 and 67 and the contact holes 66 and 68. Subsequently, a lower seed layer 73 may be formed on the substrate 51 having the barrier metal layer 71. In this case, the lower seed layer 73 may not be formed.

Before the barrier metal layer 71 is formed, the lower conductive patterns 55 and 56 exposed within the contact holes 66 and 68 may be cleaned.

The barrier metal layer 71 may be formed of one selected from the group consisting of Ta, TaN, Ti, TiN, TiSiN and WN, or a combination layer thereof. The barrier metal layer 71 may be formed to a thickness of 1 nm to 100 nm. In addition, it is preferable that the barrier metal layer 71 conformally covers inner walls of the trenches 65 and 67 and the contact holes 66 and 68.

The lower seed layer 73 may be formed of a conductive material layer where a surface insulating layer is not easily formed. In this case, the lower seed layer 73 may be formed of one selected from the group consisting of Cu, Pt, Pd, Ni, Ag, and Au, or an alloy layer thereof. In addition, the lower seed layer 73 may be formed by a physical vapor deposition (PVD) method, a chemical vapor deposition (CVD) method, or an electroless plating method. In the exemplary embodiments of the present invention, the lower seed layer 73 may be formed of a copper layer having a thickness of about 10 nm to 500 nm by the PVD method. The lower seed layer 73 may also conformally cover inner walls of the trenches 65 and 67 and the contact holes 66 and 68.

As a result, the inner walls of the trenches 65 and 67 and the contact holes 66 and 68 may be conformally covered by the barrier metal layer 71 and the lower seed layer 73 which are sequentially stacked.

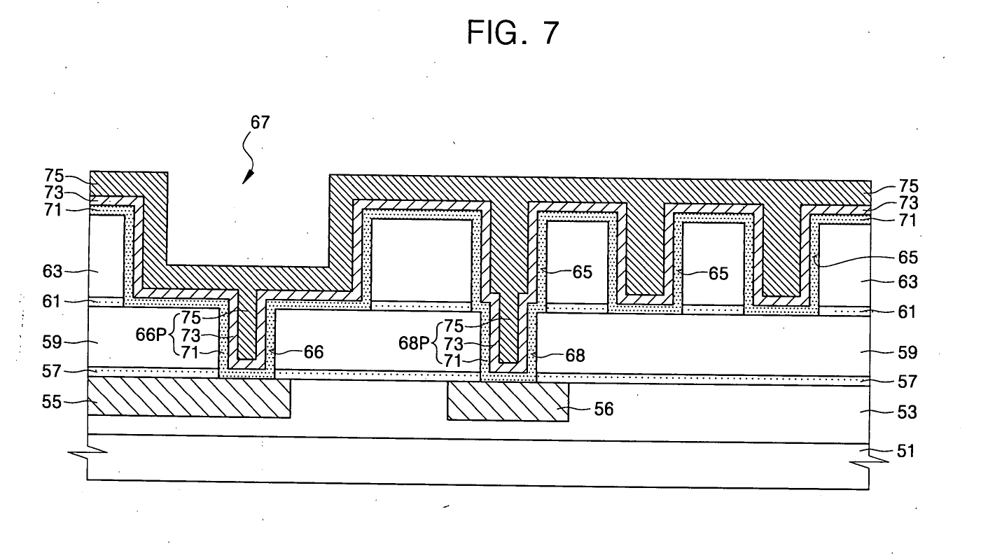

Referring to FIG. 7, a lower copper layer 75 is formed on the substrate 51 having the barrier metal layer 71. The lower copper layer 75 is formed of a pure copper layer. In addition, the lower copper layer 75 completely fills the first trenches 65 and the contact holes 66 and 68 and conformally covers the inside of the second trench 67.

The lower copper layer 75 may be formed by an electroplating method using the lower seed layer 73 as a conductive layer. In addition, the lower copper layer 75 may be formed by a CVD method or an electroless plating method.

The lower copper layer 75 may be formed to a thickness enough to completely fill the first trenches 65 and the contact holes 66 and 68. In this case, the lower copper layer 75 may be formed to a thickness of 50 nm to 1000 nm. As a result, preliminary contact plugs 66P and 68P may be formed within the contact holes 66 and 68. Each of the preliminary contact plugs 66P and 68P may be formed of the barrier metal layer 71, the lower seed layer 73, and the lower copper layer 75 which are sequentially stacked.

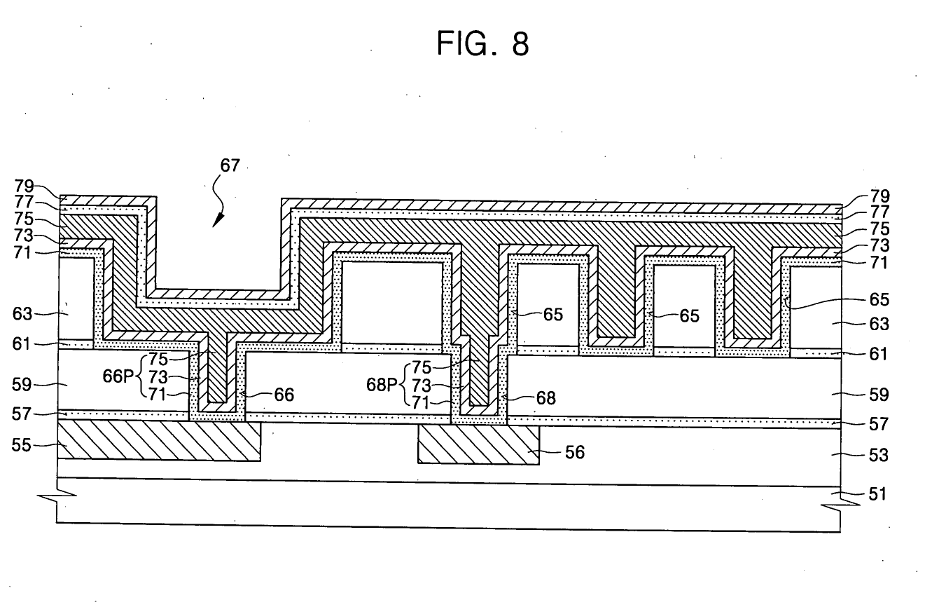

Referring to FIG. 8, an additive material layer 77 is formed on the substrate 51 having the lower copper layer 75. The additive material layer 77 conformally covers the inside of the second trench 67. In this case, a bottom surface of the additive material layer 77 is lower than a top surface of the upper inter-level dielectric 63. The first trenches 65 are completely filled with the lower copper layer 75. Accordingly, the additive material layer 77 is formed on the lower copper layer 75. That is, the additive material layer 77 is not present in the first trenches 65.

The additive material layer 77 may be formed by a PVD method, a CVD method, an electroplating method, or an electroless plating method. In addition, the thickness of the additive material layer 77 may be adjusted based on a desired alloy ratio. For example, the additive material layer 77 may be formed to a thickness of about 1 nm to 1000 nm. The additive material layer 77 may be formed of one selected from the group consisting of Al, Sn, Pb, Zn, Pt, Pd, Ni, Ag, Au, In, Mg, a Cu—Al alloy, and a Cu—Sn alloy, or an alloy layer thereof.

An upper seed layer 79 may be formed on the substrate 51 having the additive material layer 77. In this case, the upper seed layer 79 may be omitted.

It is preferable that the upper seed layer 79 is also formed of a conductive material layer where a surface insulating layer is not easily formed. In this case, the upper seed layer 79 may be formed of one selected from the group consisting of Cu, Pt, Pd, Ni, Ag, and Au, or an alloy layer thereof. In addition, the upper seed layer 79 may be formed by a PVD method, a CVD method, or an electroless plating method. In the exemplary embodiments of the present invention, the upper seed layer 79 may be formed of a copper layer having a thickness of about 10 nm to 2000 nm by the PVD method. The upper seed layer 79 may also conformally cover the inside of the second trench 67. Alternatively, the upper seed layer 79 may be thick enough to completely fill the inside of the second trench 67.

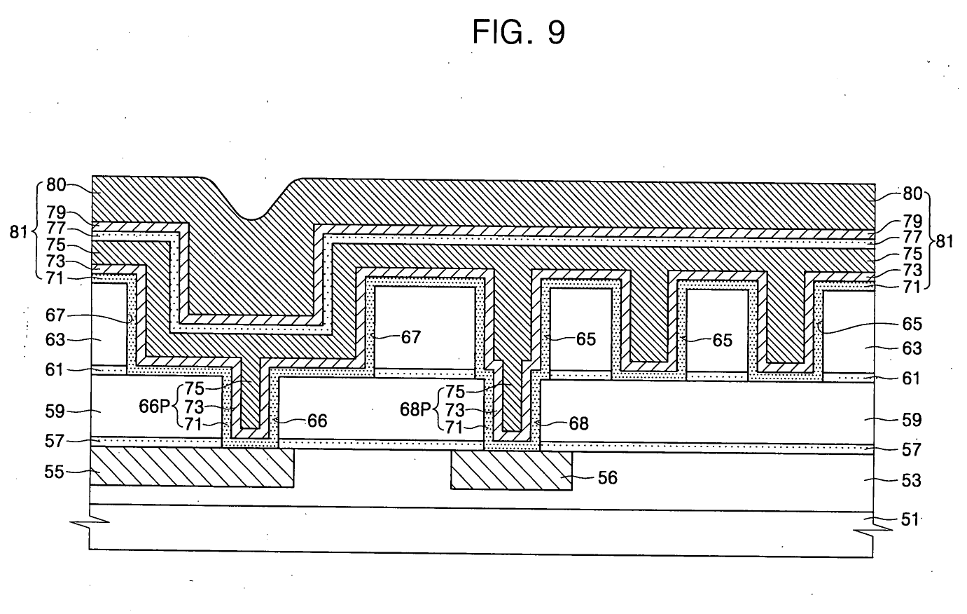

Referring to FIG. 9 an upper copper layer 80 may be formed on the substrate 51 having the additive material layer 77. The upper copper layer 80 may also be formed of a pure copper layer. The upper copper layer 80 may be formed by an electroplating method using the upper seed layer 79 as a conductive layer. In addition, the upper copper layer 80 may be formed by an electroplating method using the additive material layer 77 and the lower copper layer 75 as conductive layers. In addition, the upper copper layer 80 may be formed by a CVD method or an electroless plating method

The upper copper layer 80 preferably has a thickness sufficient to completely fill the inside of the second trench 67. For example, the upper copper layer 80 may be formed to a thickness of about 100 nm to 2000 nm.

Alternatively, when the upper seed layer 79 is thick enough to completely fill the inside of the second trench 67, the upper copper layer 80 may be omitted.

As a result, a metal combination layer 81 may be formed on the substrate 51. The metal combination layer 81 may be formed of the barrier metal layer 71, the lower seed layer 73, the lower copper layer 75, the additive material layer 77, the upper seed layer 79, and the upper copper layer 80, which are sequentially stacked.

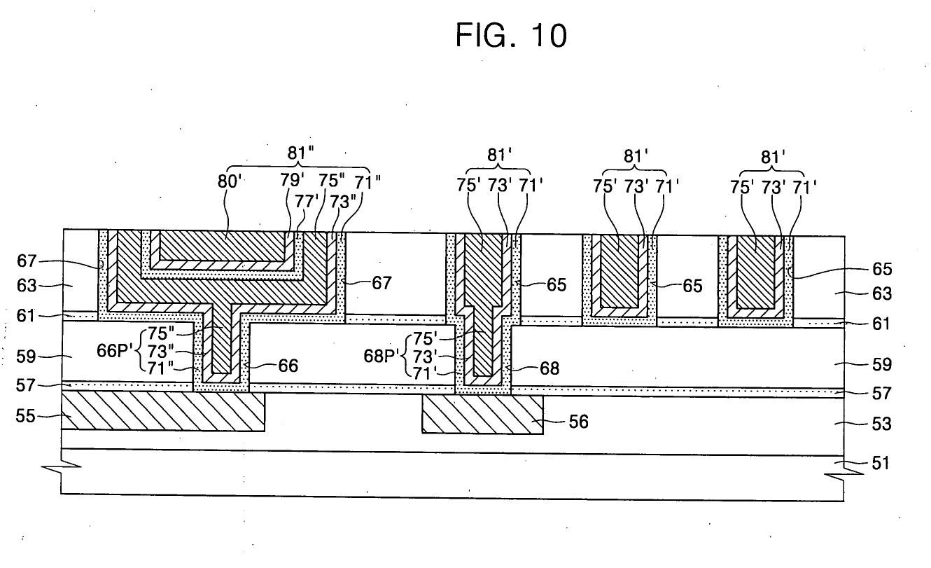

Referring to FIG. 10, the substrate 51 having the metal combination layer 81 may be annealed at a low temperature to form a grain boundary. The low temperature annealing may be performed at a temperature of, for example, 20° C. to 300° C. for 1 min to 3600 min. For example, when the additive material layer 77 contains Al, the low temperature annealing may be performed at a temperature of about 80° C. to 200° C. for about 5 min to 30 min. When the additive material layer 77 contains Sn, the low temperature annealing may be performed at a temperature of about 20° C. to 100° C. Alternatively, the low temperature annealing may be skipped.

Subsequently, the metal combination layer 81 is planarized to expose the upper inter-level dielectric 63. A chemical mechanical polishing (CMP) process employing the upper inter-level dielectric 63 as a stop layer may be applied for the planarization. Alternatively, the CMP process may be divided into a first CMP process and a second CMP process to perform the planarization. The first CMP process may employ the barrier metal layer 71 as a stop layer. The second CMP process may employ the upper inter-level dielectric 63 as a stop layer.

As a result, first interconnections 81′ are formed within the first trenches 65. At the same time, a preliminary interconnection 81″ is formed within the second trench 67. Each of the first interconnections 81′ may be formed of a first barrier metal pattern 71′, a first lower seed pattern 73′, and a first pure copper pattern 75′ which are sequentially stacked. In addition, each of the first interconnections 81′ may also be formed of the first barrier metal pattern 71′ and the first pure copper pattern 75′ which are sequentially stacked. As shown in FIG. 9, the first trenches 65 are filled with the lower copper layer 75. Accordingly, the additive material layer 77 does not remain within the first interconnections 81′. That is, the additive material layer 77 deposited above the first trenches 65 is completely removed by the planarization.

In contrast, the additive material layer 77 is conformally deposited within the second trench 67 such that a bottom surface of the additive material layer 77 is lower than a top surface of the upper inter-level dielectric 63. Accordingly, the preliminary interconnection 81″ may be formed of a second barrier metal pattern 71″, a second lower seed pattern 73″, a second pure copper pattern 75″, an additive material pattern 77′, an upper seed pattern 79′, and an upper pure copper pattern 80′ which are sequentially stacked. In addition, the preliminary interconnection 81″ may be formed of the second barrier metal pattern 71″, the second pure copper pattern 75″, the additive material pattern 77′, and the upper pure copper pattern 80′ which are sequentially stacked. Further, the preliminary interconnection 81″ may also be formed of the second barrier metal pattern 71″, the second pure copper pattern 75″, and the additive material pattern 77′ which are sequentially stacked.

While the preliminary interconnection 81″ is formed, a contact plug 66P′ may be formed within the contact hole 66. The contact plug 66P′ may be formed of the second barrier metal pattern 71″, the second lower seed pattern 73″, and the second pure copper pattern 75″ which are sequentially stacked.

In addition, while the first interconnections 81′ are formed, another contact plug 68P′ may be formed within the other contact hole 68. The other contact plug 68P′ may be formed of the first barrier metal pattern 71′, the first lower seed pattern 73′, and the first pure copper pattern 75′ which are sequentially stacked.

Referring to FIG. 11, the preliminary interconnection 81″ is annealed to form a second interconnection 86. The annealing may include a process of heating the substrate 51 having the preliminary interconnection 81″ at a temperature of about 150° C. to 700° C. for about 1 min to 3600 min. For example, when the additive material pattern 77′ contains Al, the annealing may be performed at a temperature of about 250° C. to 450° C. When the additive material pattern 77′ contains Sn, the annealing may be performed at a temperature of about 150° C. to 230° C.

The annealing causes a copper alloy pattern 85 to be formed within the second trench 67. That is, while the preliminary interconnection 81″ is annealed, all the second lower seed pattern 73″, the second pure copper pattern 75″, the additive material pattern 77′, the upper seed pattern 79′, and the upper pure copper pattern 80′ may be transformed to a copper alloy so that the copper alloy pattern 85 may be formed. In this case, the second interconnection 86 may be formed of the second barrier metal pattern 71″ and the copper alloy pattern 85 which are sequentially stacked.

While the preliminary interconnection 81″ is annealed, the contact plug 66P′ may also be transformed to a copper alloy plug 66P″. The copper alloy plug 66P″ may be formed of the second barrier metal pattern 71″ and the copper alloy pattern 85 which are sequentially stacked. The copper alloy plug 66P″ may act to electrically connect the second interconnection 86 to the lower conductive pattern 55.

In contrast, the additive material layer 77 does not remain within the first trenches 65. Accordingly, while the preliminary interconnection 81″ is annealed, the first interconnections 81′ are not transformed to a copper alloy. That is, the first interconnections 81′ may be formed of the first barrier metal pattern 71′, the first lower seed pattern 73′, and the first pure copper pattern 75′ which are sequentially stacked. In addition, the first interconnections 81′ may be formed of the first barrier metal pattern 71′ and the first pure copper pattern 75′ which are sequentially stacked.

Consequently, the first interconnections 81′ may include the first pure copper pattern 75′, and the second interconnection 86 may include the copper alloy pattern 85. In addition, top surfaces of the first interconnections 81′, the second interconnection 86, and the upper inter-level dielectric 63 may be formed substantially on the same plane. In addition, the second interconnection 86 may have a larger width than the first interconnections 81′.

As described above, the first pure copper pattern 75′ is formed of a pure copper layer. Accordingly, the first interconnections 81′ have low resistance. In contrast, the copper alloy pattern 85 may be formed of an alloy layer of the second lower seed pattern 73″, the second pure copper pattern 75″, the additive material pattern 77′, the upper seed pattern 79′, and the upper pure copper pattern 80′. The additive material pattern 77′ may be formed of one selected from the group consisting of Al, Sn, Pb, Zn, Pt, Pd, Ni, Ag, Au, In, Mg, a Cu—Al alloy, and a Cu—Sn alloy, or an alloy layer thereof. Accordingly, the second interconnection 86 has good reliability.

Hereinafter, methods of forming a semiconductor device having a selective copper alloy interconnection according to other embodiments of the present invention will be described with reference to FIGS. 12 to 15.

Referring to FIG. 12, the same method as that described with reference to FIGS. 5 to 8 is employed to sequentially form the barrier metal layer 71, the lower seed layer 73, the lower copper layer 75, and the additive material layer 77. Subsequently, the upper barrier metal layer 78 may be formed to cover the additive material layer 77.

The upper barrier metal layer 78 may be formed of one selected from the group consisting of Ta, TaN, Ti, TiN, TiSiN and WN, or a combination layer thereof. The upper barrier metal layer 78 may be formed to a thickness of about 1 nm to 100 nm. In addition, it is preferable that the upper barrier metal layer 78 conformally covers an inner wall of the second trench 67. In this case, a bottom surface of the upper barrier metal layer 78 may be lower than a top surface of the upper inter-level dielectric 63.

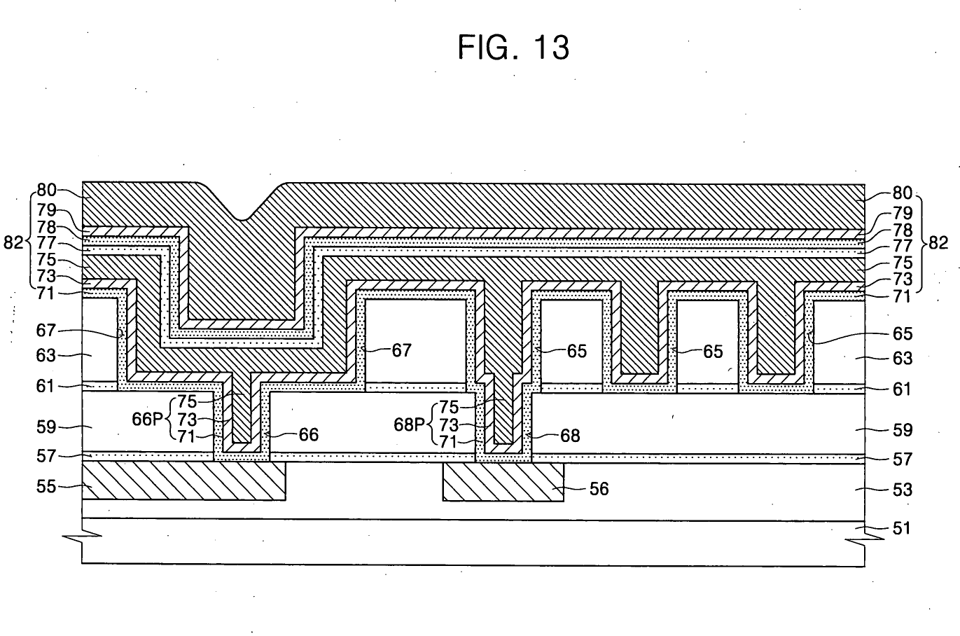

Referring to FIG. 13, an upper seed layer 79 may be formed on the substrate 51 having the upper barrier metal layer 78. A bottom surface of the upper seed layer 79 may be lower than a top surface of the upper inter-level dielectric 63. The upper seed layer 79 may be formed of a conductive material layer where a surface insulating layer is not easily formed. In this case, the upper seed layer 79 may be formed of one selected from the group consisting of Cu, Pt, Pd, Ni, Ag and Au, or an alloy layer thereof. Alternatively, the upper seed layer 79 may be omitted.

An upper copper layer 80 may be formed on the substrate 51 having the upper seed layer 79. A bottom surface of the upper copper layer 80 may be lower than a top surface of the upper inter-level dielectric 63. In addition, the upper copper layer 80 may be thick enough to completely fill the inside of the second trench 67. Alternatively, when the upper seed layer 79 is thick enough to completely fill the inside of the second trench 67, the upper copper layer 80 may be omitted.

As a result, a metal combination layer 82 may be formed on the substrate 51. The metal combination layer 82 may be formed of the barrier metal layer 71, the lower seed layer 73, the lower copper layer 75, the additive material layer 77, the upper barrier metal layer 78, the upper seed layer 79, and the upper copper layer 80 which are sequentially stacked.

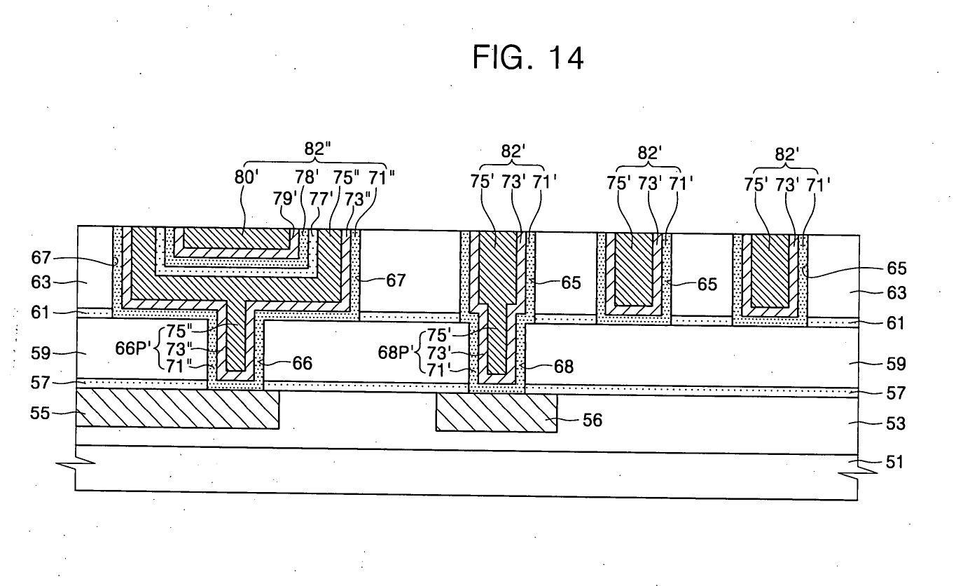

Referring to FIG. 14, the substrate 51 having the metal combination layer 82 may be annealed at a low temperature to form a grain boundary. Alternatively, the low temperature annealing may be skipped.

Subsequently, the metal combination layer 82 is planarized to expose the upper inter-level dielectric 63.

As a result, first interconnections 82′ are formed within the first trenches 65. At the same time, a preliminary interconnection 82″ is formed within the second trench 67. Each of the first interconnections 82′ may be formed of a first barrier metal pattern 71′, a first lower seed pattern 73′, and a first pure copper pattern 75′ which are sequentially stacked. In addition, each of the first interconnections 82′ may also be formed of the first barrier metal pattern 71′ and the first pure copper pattern 75′ which are sequentially stacked. As shown in FIG. 9, the first trenches 65 are filled with the lower copper layer 75. Accordingly, the additive material layer 77 does not remain within the first interconnections 82′. That is, the additive material layer 77 deposited above the first trenches 65 is completely removed by the planarization.

In contrast, the additive material layer 77 is conformally deposited within the second trench 67 such that a bottom surface of the additive material layer 77 is lower than a top surface of the upper inter-level dielectric 63. A bottom surface of the upper barrier metal layer 78 is also lower than a top surface of the upper inter-level dielectric 63. Accordingly, the preliminary interconnection 82″ may be formed of a second barrier metal pattern 71″, a second lower seed pattern 73″, a second pure copper pattern 75″, an additive material pattern 77′, an upper barrier metal pattern 78′, an upper seed pattern 79′, and an upper pure copper pattern 80′ which are sequentially stacked. In addition, the preliminary interconnection 82″ may also be formed of the second barrier metal pattern 71″, the second pure copper pattern 75″, the additive material pattern 77′, the upper barrier metal pattern 78′, and the upper pure copper pattern 80′ which are sequentially stacked. Further, the preliminary interconnection 82″ may also be formed of the second barrier metal pattern 71″, the second pure copper pattern 75″, the additive material pattern 77′, and the upper barrier metal pattern 78′ which are sequentially stacked.

While the preliminary interconnection 82″ is formed, a contact plug 66P′ may be formed within the contact hole 66. The contact plug 66P′ may be formed of the second barrier metal pattern 71″, the second lower seed pattern 73″, and the second pure copper pattern 75″ which are sequentially stacked.

In addition, while the first interconnections 82′ are formed, another contact plug 68P′ may be formed within the other contact hole 68. The other contact plug 68P′ may be formed of the first barrier metal pattern 71′, the first lower seed pattern 73′, and the first pure copper pattern 75′ which are sequentially stacked.

Referring to FIG. 15, the preliminary interconnection 82″ is annealed to form a second interconnection 87. The annealing may include a process of heating the substrate 51 having the preliminary interconnection 82″ at a temperature of about 150° C. to 700° C. for about 1 min to 3600 min. For example, when the additive material pattern 77′ contains the Al, the annealing may be performed at a temperature of about 250° C. to 450° C. When the additive material pattern 77′ contains Sn, the annealing may be performed at a temperature of about 150° C. to 230° C.

The annealing causes a copper alloy pattern 85 to be formed within the second trench 67. That is, while the preliminary interconnection 82″ is annealed, all the second lower seed pattern 73″, the second pure copper pattern 75″, and the additive material pattern 77′ may be transformed to a copper alloy so that the copper alloy pattern 85 may be formed. In contrast, the upper barrier metal pattern 78′ blocks the alloy formation of the upper seed pattern 79′ and the upper pure copper pattern 80′. That is, the upper seed pattern 79′ and the upper pure copper pattern 80′ may remain on the upper barrier metal pattern 78′. In this case, the second interconnection 87 may be formed of the second barrier metal pattern 71″, the copper alloy pattern 85, the upper barrier metal pattern 78′, the upper seed pattern 79′, and the upper pure copper pattern 80′ which are sequentially stacked.

While the preliminary interconnection 82″ is annealed, the contact plug 66P′ may also be transformed to a copper alloy plug 66P″. The copper alloy plug 66P″ may be formed of the second barrier metal pattern 71″ and the copper alloy pattern 85 which are sequentially stacked. The copper alloy plug 66P″ may act to electrically connect the second interconnection 87 to the lower conductive pattern 55.

In contrast, the additive material layer 77 does not remain within the first trenches 65. Accordingly, while the preliminary interconnection 82″ is annealed, the first interconnections 82′ are not transformed to a copper alloy. That is, the first interconnections 82′ may be formed of the first barrier metal pattern 71′, the first lower seed pattern 73′, and the first pure copper pattern 75′ which are sequentially stacked. In addition, the first interconnections 82′ may be formed of the first barrier metal pattern 71′ and the first pure copper pattern 75′ which are sequentially stacked.

Consequently, the first interconnections 82′ may include the first pure copper pattern 75′ and the second interconnection 87 may include the copper alloy pattern 85. In addition, top surfaces of the first interconnections 82′, the second interconnection 87, and the upper inter-level dielectric 63 may be formed substantially on the same plane. In addition, the second interconnection 87 may have a larger width than the first interconnections 82′.

Hereinafter, methods of forming a semiconductor device having a selective copper alloy interconnection according to yet other exemplary embodiments of the present invention will be described with reference to FIGS. 16 to 19.

Referring to FIG. 16, the same method as that described with reference to FIGS. 5 to 7 is employed to sequentially form the barrier metal layer 71, the lower seed layer 73, and the lower copper layer 75. Subsequently, an intermediate barrier metal layer 76 may be formed to cover the lower copper layer 75.

The intermediate barrier metal layer 76 may be formed of one selected from the group consisting of Ta, TaN, Ti, TiN, TiSiN and WN, or a combination layer thereof. The intermediate barrier metal layer 76 may be formed to a thickness of about 1 nm to 100 nm. In addition, it is preferable that the intermediate barrier metal layer 76 conformally covers an inner wall of the second trench 67. In this case, a bottom surface of the intermediate barrier metal layer 76 may be lower than a top surface of the upper inter-level dielectric 63.

Subsequently, an additive material layer 77 is formed on the intermediate barrier metal layer 76. The additive material layer 77 conformally covers the inside of the second trench 67. In this case, a bottom surface of the additive material layer 77 is lower than a top surface of the upper inter-level dielectric 63.

The additive material layer 77 may be formed of one selected from the group consisting of Al, Sn, Pb, Zn, Pt, Pd, Ni, Ag, Au, In, Mg, a Cu—Al alloy, and a Cu—Sn alloy, or an alloy layer thereof.

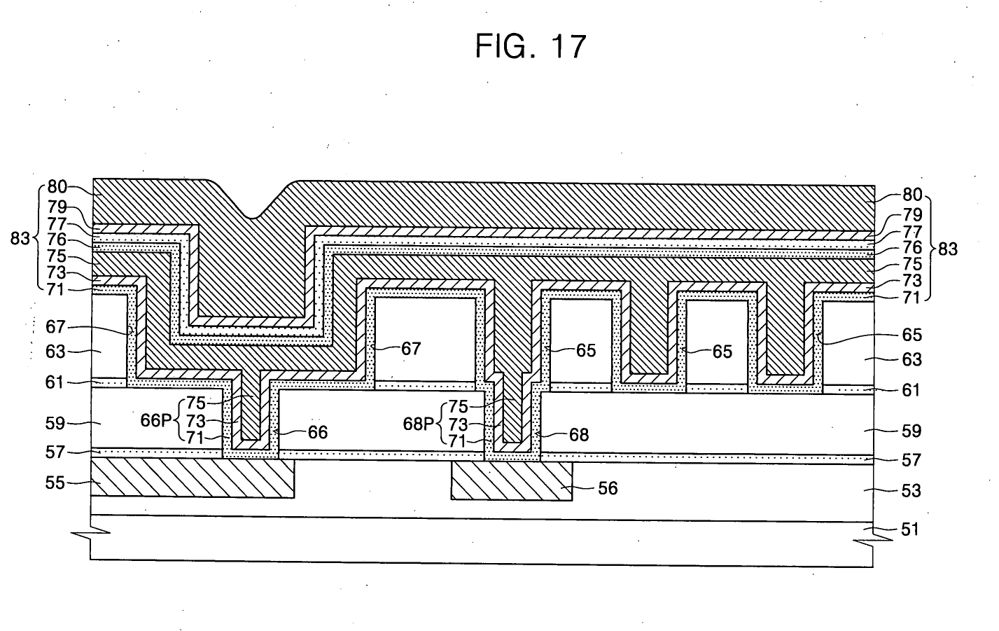

Referring to FIG. 17, an upper seed layer 79 may be formed on the substrate 51 having the additive material layer 77. A bottom surface of the upper seed layer 79 may be lower than a top surface of the upper inter-level dielectric 63.

The upper seed layer 79 may be formed of a conductive material layer where a surface insulating layer is not easily formed. However, the upper seed layer 79 may be omitted.

An upper copper layer 80 may be formed on the substrate 51 having the additive material layer 77. A bottom surface of the upper copper layer 80 may be lower than a top surface of the upper inter-level dielectric 63. The upper copper layer 80 may be formed of a pure copper layer. The upper copper layer 80 may be thick enough to completely fill the inside of the second trench 67. In this case, the upper copper layer 80 may be formed to a thickness of about 100 nm to 2000 nm. Alternatively, when the upper seed layer 79 is thick enough to completely fill the inside of the second trench 67, the upper copper layer 80 may be omitted.

As a result, a metal combination layer 83 may be formed on the substrate 51. The metal combination layer 83 may be formed of the barrier metal layer 71, the lower seed layer 73, the lower copper layer 75, the intermediate barrier metal layer 76, the additive material layer 77, the upper seed layer 79, and the upper copper layer 80 which are sequentially stacked.

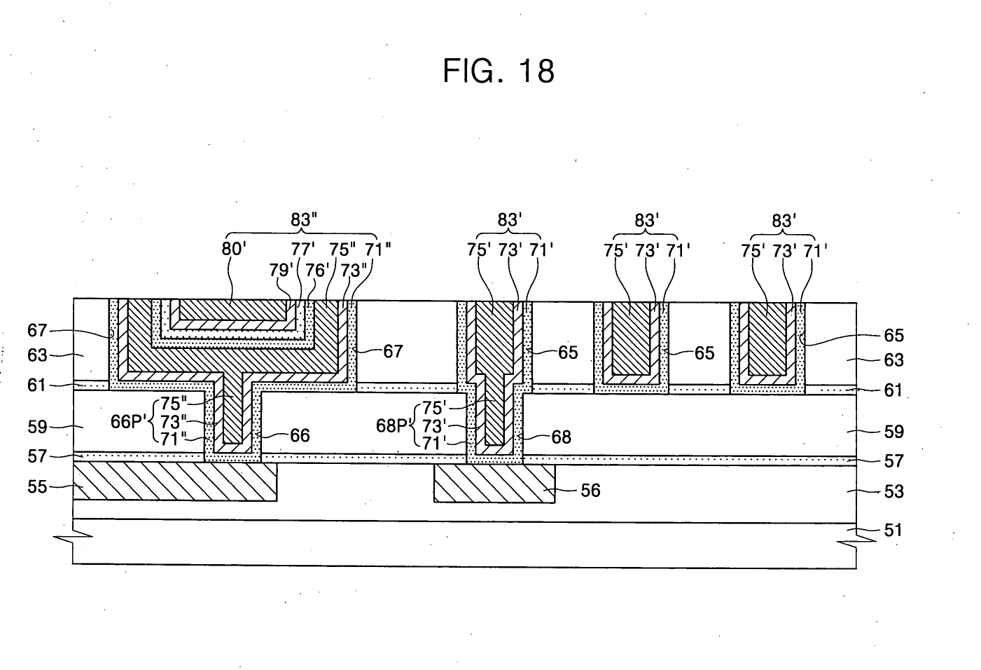

Referring to FIG. 18, the substrate 51 having the metal combination layer 83 may be annealed at a low temperature to form a grain boundary. Alternatively, the low temperature annealing may be skipped.

Subsequently, the metal combination layer 83 is planarized to expose the upper inter-level dielectric 63.

As a result, first interconnections 83′ are formed within the first trenches 65. At the same time, a preliminary interconnection 83″ is formed within the second trench 67. Each of the first interconnections 83′ may be formed of a first barrier metal pattern 71′, a first lower seed pattern 73′, and a first pure copper pattern 75′ which are sequentially stacked. In addition, each of the first interconnections 83′ may also be formed of the first barrier metal pattern 71′ and the first pure copper pattern 75′ which are sequentially stacked. As shown in FIG. 9, the first trenches 65 are filled with the lower copper layer 75. Accordingly, the additive material layer 77 does not remain within the first interconnections 83′. That is, the additive material layer 77 deposited above the first trenches 65 is completely removed by the planarization.

In contrast, the additive material layer 77 is conformally deposited within the second trench 67 such that a bottom surface of the additive material layer 77 is lower than a top surface of the upper inter-level dielectric 63. A bottom surface of the intermediate barrier metal layer 76 is also lower than a top surface of the upper inter-level dielectric 63. Accordingly, the preliminary interconnection 83″ may be formed of a second barrier metal pattern 71″, a second lower seed pattern 73″, a second pure copper pattern 75″, an intermediate barrier metal pattern 76′, an additive material pattern 77′, an upper seed pattern 79′, and an upper pure copper pattern 80′ which are sequentially stacked. In addition, the preliminary interconnection 83″ may also be formed of the second barrier metal pattern 71″, the second pure copper pattern 75″, the intermediate barrier metal pattern 76′, the additive material pattern 77′, and the upper pure copper pattern 80′ which are sequentially stacked.

While the preliminary interconnection 83″ is formed, a contact plug 66P′ may be formed within the contact hole 66. The contact plug 66P′ may be formed of the second barrier metal pattern 71″, the second lower seed pattern 73″, and the second pure copper pattern 75″ which are sequentially stacked

In addition, while the first interconnections 83′ are formed, another contact plug 68P′ may be formed within the other contact hole 68. The other contact plug 68P′ may be formed of the first barrier metal pattern 71′, the first lower seed pattern 73′, and the first pure copper pattern 75′ which are sequentially stacked.

Referring to FIG. 19, the preliminary interconnection 83″ is annealed to form a second interconnection 88. The annealing may include a process of heating the substrate 51 having the preliminary interconnection 83″ at a temperature of about 150° C. to 700° C. for about 1 min to 3600 min. For example, when the additive material pattern 77′ contains the Al, the annealing may be performed at a temperature of about 250° C. to 450° C. When the additive material pattern 77′ contains Sn, the annealing may be performed at a temperature of about 150° C. to 230° C.

The annealing causes a copper alloy pattern 85 to be formed within the second trench 67. That is, while the preliminary interconnection 83″ is annealed, all the additive material pattern 77′, the upper seed pattern 79′, and the upper pure copper pattern 80′ may be transformed to a copper alloy so that the copper alloy pattern 85 may be formed.

In contrast, the intermediate barrier metal pattern 76′ blocks the alloy formation of the second lower seed pattern 73″ and the second pure copper pattern 75″. That is, the second lower seed pattern 73″ and the second pure copper pattern 75″ may remain on the intermediate barrier metal pattern 76′. In this case, the second interconnection 88 may be formed of the second barrier metal pattern 71″, the second lower seed pattern 73″, the second pure copper pattern 75″, the intermediate barrier metal pattern 76′, and the copper alloy pattern 85 which are sequentially stacked.

The additive material layer 77 does not remain within the first trenches 65. Accordingly, while the preliminary interconnection 83″ is annealed, the first interconnections 83′ are not transformed to a copper alloy. That is, the first interconnections 83′ may be formed of the first barrier metal pattern 71′, the first lower seed pattern 73′, and the first pure copper pattern 75′ which are sequentially stacked. In addition, the first interconnections 83′ may be formed of the first barrier metal pattern 71′ and the first pure copper pattern 75′ which are sequentially stacked.

Consequently, the first interconnections 83′ may include the first pure copper pattern 75′ and the second interconnection 88 may include the copper alloy pattern 85. In addition, top surfaces of the first interconnections 83′, the second interconnection 88, and the upper inter-level dielectric 63 may be formed substantially on the same plane. In addition, the second interconnection 88 may have a larger width than the first interconnections 83′.

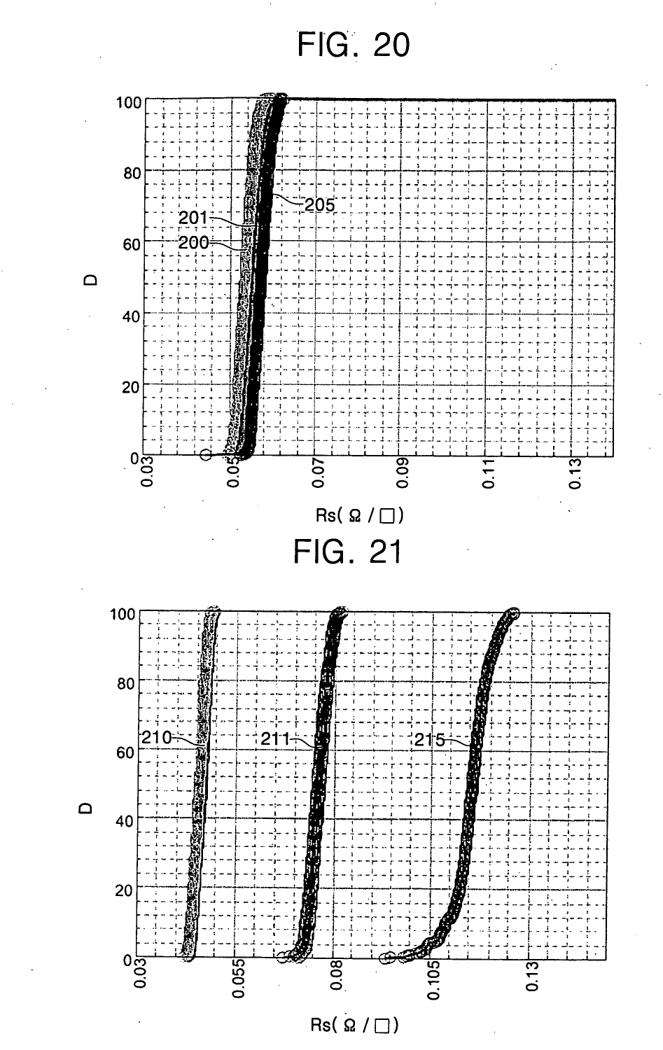

FIGS. 20 and 21 are characteristic diagrams showing sheet resistances of a selective copper alloy interconnection fabricated in accordance with embodiments of the present invention. Horizontal axes in FIGS. 20 and 21 indicate the sheet resistances and the unit is Ω/square. Vertical axes in FIGS. 20 and 21 indicate accumulated distributions and the unit is %.

First, the fabrication history of the selective copper alloy interconnection will be described in brief. An inter-level dielectric is formed on a semiconductor substrate. Trenches are formed within the inter-level dielectric. A barrier metal layer is formed to conformally cover inner walls of the trenches. Metal combination layers having different thicknesses from each other are formed on the semiconductor substrate having the barrier metal layer, and then annealed at a low temperature of about 200° C. for about 5 min. A CMP process is employed to form first interconnections and a preliminary interconnection, which is then annealed at a temperature of about 350° C. for about 30 min to form a second interconnection. The first and second interconnections are formed to a thickness of about 520 nm.

Referring to FIG. 20, the curve 200 is a sheet resistance measured when the first interconnection is formed of a lower copper layer having a thickness of about 800 nm with an interconnection width of about 0.2 μm. The curve 201 is a sheet resistance measured when the first interconnection is formed of a lower copper layer of about 100 nm, an aluminum layer of about 10 nm, and an upper copper layer of about 760 nm, with an interconnection width of about 0.2 μm. And the curve 205 is a sheet resistance measured when the first interconnection is formed of a lower copper layer of about 100 nm, an aluminum layer of 50 nm, and an upper copper layer of about 760 nm, with an interconnection width of about 0.2 μm.

As shown in FIG. 20, all of the curves 200, 201, and 205 showed a sheet resistance of 0.055Ω/square at a distribution of 80%. That is, it can be seen that each of the first interconnections having an interconnection width of 0.2 μm may be formed of a pure copper pattern.

Referring to FIG. 21, the curve 210 is a sheet resistance measured when the second interconnection is formed of a lower copper layer having a thickness of about 800 nm with an interconnection width of about 1.0 μm. The curve 211 is a sheet resistance measured when the second interconnection is formed of a lower copper layer of about 100 nm, an aluminum layer of about 10 nm, and an upper copper layer of about 760 nm, with an interconnection width of about 1.0 μm. And the curve 215 is a sheet resistance measured when the first interconnection is formed of a lower copper layer of about 100 nm, an aluminum layer of about 50 nm, and an upper copper layer of about 760 nm, with an interconnection width of about 1.0 μm.

As shown in FIG. 21, the curves 210, 211, and 215 showed sheet resistances of 0.05Ω/square, 0.08Ω/square, and 0.12Ω/square, respectively, at a distribution of 80%. That is, it can be seen that each of the second interconnections having an interconnection width of 1.0 μm may be formed of a copper aluminum alloy pattern by means of the aluminum layer. In addition, it can be seen that the alloy rate of the copper aluminum alloy pattern may be adjusted in response to a thickness of the aluminum layer.

According to the present invention as described above, a first interconnection and a second interconnection having a larger width than the first interconnection are formed on a substrate. The first interconnection has a pure copper pattern. The second interconnection has a copper alloy pattern. Accordingly, the first interconnection has low resistance. In contrast, the second interconnection has good reliability. Consequently, a selective copper alloy interconnection in a semiconductor device may be implemented which is capable of enhancing reliability of a wide interconnection while preventing a resistance increase in a narrow interconnection.

The present invention is not limited to the above-described embodiments but may be applied to other cases within a spirit of the present invention. For example, the present invention may also be applied to a is selective copper alloy interconnection in a semiconductor device using a single damascene process and its fabrication method.

What is claimed is:

1. A selective copper alloy interconnection in a semiconductor device, comprising:
a substrate;
a dielectric formed on the substrate;
a first interconnection formed in the dielectric; and
a second interconnection formed in the dielectric and having a larger width than the first interconnection,
wherein the first interconnection has a first pure copper pattern, and the second interconnection has a copper alloy pattern.

2. The selective copper alloy interconnection according to claim 1, wherein the copper alloy pattern is an alloy layer formed of copper (Cu) and an additive material.

3. The selective copper alloy interconnection according to claim 2, wherein the additive material is at least one selected from the group consisting of aluminum (Al), tin (Sn), lead (Pb), zinc (Zn), platinum (Pt), palladium (Pd), nickel (Ni), silver (Ag), gold (Au), indium (In), magnesium (Mg), a copper-aluminum (Cu—Al) alloy, and a copper-tin (Cu—Sn) alloy.

4. The selective copper alloy interconnection according to claim 1, wherein the first interconnection comprises the first pure copper pattern and a first lower seed pattern disposed to surround sidewalls and bottom surfaces of the first pure copper pattern.

5. The selective copper alloy interconnection according to claim 1, wherein the first interconnection comprises the first pure copper pattern and a first barrier metal pattern disposed to surround sidewalls and bottom surfaces of the first pure copper pattern, and the second interconnection comprises the copper alloy pattern and a second barrier metal pattern disposed to surround sidewalls and bottom surfaces of the copper alloy pattern.

6. The selective copper alloy interconnection according to claim 1, wherein the second interconnection comprises the copper alloy pattern and an upper pure copper pattern deposited on the copper alloy pattern.

7. The selective copper alloy interconnection according to claim 6, wherein the second interconnection comprises the copper alloy pattern, the upper pure copper pattern, and an upper barrier metal pattern deposited on the copper alloy pattern.

8. The selective copper alloy interconnection according to claim 7, wherein the second interconnection comprises the copper alloy pattern, the upper pure copper pattern, the upper barrier metal pattern, and an upper seed pattern interposed between the upper barrier metal pattern and the upper pure copper pattern.

9. The selective copper alloy interconnection according to claim 1, wherein the second interconnection comprises the copper alloy pattern and a second pure copper pattern disposed to surround sidewalls and a bottom surface of the copper alloy pattern.

10. The selective copper alloy interconnection according to claim 9, wherein the second interconnection comprises the copper alloy pattern, the second pure copper pattern, and an intermediate barrier metal pattern interposed between the copper alloy pattern and the second pure copper pattern.

11. The selective copper alloy interconnection according to claim 9, wherein the second interconnection comprises the copper alloy pattern, the second pure copper pattern, and a second lower seed pattern disposed to surround sidewalls and a bottom surface of the second pure copper pattern.

12. The selective copper alloy interconnection according to claim 9, wherein the second interconnection comprises the copper alloy pattern, the second pure copper pattern, and a second barrier metal pattern disposed to surround sidewalls and a bottom surface of the second pure copper pattern.

13. A selective copper alloy interconnection in a semiconductor device, comprising:
a substrate;
a dielectric formed on the substrate;
a first interconnection formed in the dielectric;
a second interconnection formed in the dielectric and having a larger width than the first interconnection;
a first lower conductive pattern formed below the second interconnection and spaced apart from the second interconnection; and
a contact plug penetrating the dielectric and disposed between the lower conductive pattern and the second interconnection,
wherein the first interconnection has a first pure copper pattern, the second interconnection has a copper alloy pattern, and one end of the contact plug is in contact with the lower conductive pattern and the other end of the contact plug is in contact with the second interconnection.

14. The selective copper alloy interconnection according to claim 13, wherein the copper alloy pattern is an alloy layer formed of copper (Cu) and an additive material.

15. The selective copper alloy interconnection according to claim 14, wherein the additive material is at least one selected from the group consisting of aluminum (Al), tin (Sn), lead (Pb), zinc (Zn), platinum (Pt), palladium (Pd), nickel (Ni), silver (Ag), gold (Au), indium (In), magnesium (Mg), a copper-aluminum (Cu—Al) alloy, and a copper-tin (Cu—Sn) alloy.

16. The selective copper alloy interconnection according to claim 13, wherein the first interconnection comprises the first pure copper pattern and a first barrier metal pattern disposed to surround sidewalls and bottom surfaces of the first pure copper pattern, and the second interconnection comprises the copper alloy pattern and a second barrier metal pattern disposed to surround sidewalls and bottom surfaces of the copper alloy pattern.

17. The selective copper alloy interconnection according to claim 13, wherein the second interconnection comprises the copper alloy pattern and an upper pure copper pattern deposited on the copper alloy pattern.

18. The selective copper alloy interconnection according to claim 17, wherein the second interconnection comprises the copper alloy pattern, the upper pure copper pattern, and an upper barrier metal pattern interposed between the copper alloy pattern and the upper pure copper pattern.

19. The selective copper alloy interconnection according to claim 13, wherein the second interconnection comprises the copper alloy pattern and a second pure copper pattern disposed to surround sidewalls and a bottom surface of the copper alloy pattern.

20. The selective copper alloy interconnection according to claim 19, wherein the second interconnection comprises the copper alloy pattern, the second pure copper pattern, and an intermediate barrier metal pattern interposed between the copper alloy pattern and the second pure copper pattern.

21. The selective copper alloy interconnection according to claim 19, wherein the second interconnection comprises the copper alloy pattern, the second pure copper pattern, and a second barrier metal pattern disposed to surround sidewalls and a bottom surface of the second pure copper pattern.

22. The selective copper alloy interconnection according to claim 13, wherein the contact plug has the copper alloy pattern.

23. The selective copper alloy interconnection according to claim 22, wherein the contact plug comprises the copper alloy pattern and a second barrier metal pattern disposed to surround sidewalls and a bottom surface of the copper alloy pattern.

24. The selective copper alloy interconnection according to claim 13, wherein the contact plug includes a second pure copper pattern.

25. The selective copper alloy interconnection according to claim 24, wherein the contact plug comprises the second pure copper pattern and a second barrier metal pattern disposed to surround sidewalls and a bottom surface of the second pure copper pattern.

26. The selective copper alloy interconnection according to claim 13, further comprising:
a second lower conductive pattern formed below the first interconnection and spaced apart from the first interconnection; and
a second contact plug penetrating the dielectric and disposed between the second lower conductive pattern and the first interconnection,
wherein the second contact plug has the first pure copper pattern, and one end of the second contact plug is in contact with the second lower conductive pattern and the other end of the second contact plug is in contact with the first interconnection.

27. A method of forming an interconnection in a semiconductor device, comprising:
forming a dielectric on a substrate;
forming a first trench and a second trench in the dielectric, the second trench having a larger width than the first trench; and
forming a first interconnection and a second interconnection in the first and second trenches, respectively,
wherein the first interconnection includes a first pure copper pattern, and the second interconnection includes a copper alloy pattern.

28. The method according to claim 27, wherein forming the first and second interconnections comprises:
forming a metal combination layer filling the first and second trenches and covering a top surface of the substrate;
planarizing the metal combination layer and forming the first interconnection while forming a preliminary interconnection in the second trench; and
annealing the preliminary interconnection and forming the second interconnection.

29. The method according to claim 28, wherein forming the metal combination layer comprises:
forming a lower copper layer completely filling the first trench and conformally covering the inside of the second trench; and
forming an additive material layer on the substrate having the lower copper layer, a bottom surface of the additive material layer being lower than a top surface of the dielectric.

30. The method according to claim 29, wherein the additive material layer is formed of one selected from the group consisting of aluminum (Al), tin (Sn), lead (Pb), zinc (Zn), platinum (Pt), palladium (Pd), nickel (Ni), silver (Ag), gold (Au), indium (In), magnesium (Mg), a copper-aluminum (Cu—Al) alloy and a copper-tin (Cu—Sn) alloy, or an alloy layer thereof.

31. The method according to claim 29, further comprising:
before forming the lower copper layer, forming a barrier metal layer conformally covering insides of the first and second trenches.

32. The method according to claim 31, wherein the barrier metal layer is formed of one selected from the group consisting of tantalum (Ta), tantalum nitride (TaN), titanium (Ti), titanium nitride (TiN), titanium silicon nitride (TiSiN) and tungsten nitride (WN), or a combination layer thereof.

33. The method according to claim 29, further comprising:
before forming the lower copper layer, forming a lower seed layer conformally covering insides of the first and second trenches.

34. The method according to claim 33, wherein the lower seed layer is formed of one selected from the group consisting of copper (Cu), platinum (Pt), palladium (Pd), nickel (Ni), silver (Ag) and gold (Au), or an alloy layer thereof.

35. The method according to claim 29, further comprising:
after forming the additive material layer, forming an upper seed layer on the substrate having the additive material layer.

36. The method according to claim 35, wherein the upper seed layer is formed of one selected from the group consisting of copper (Cu), platinum (Pt), palladium (Pd), nickel (Ni), silver (Ag) and gold (Au), or an alloy layer thereof.

37. The method according to claim 29, further comprising:
after forming the additive material layer, forming an upper copper layer on the substrate having the additive material layer.

38. The method according to claim 37, further comprising:
before forming the upper copper layer, forming an upper barrier metal layer on the substrate having the additive material layer,
wherein the upper barrier metal layer has a bottom surface lower than a top surface of the dielectric.

39. The method according to claim 38, wherein the upper barrier metal layer is formed of one selected from the group consisting of tantalum (Ta), tantalum nitride (TaN), titanium (Ti), titanium nitride (TiN), titanium silicon nitride (TiSiN) and tungsten nitride (WN), or a combination layer thereof.

40. The method according to claim 29, further comprising:
before forming the additive material layer, forming an intermediate barrier metal layer on the substrate having the lower copper layer.

41. The method according to claim 40, wherein the intermediate barrier metal layer is formed of one selected from the group consisting of tantalum (Ta), tantalum nitride (TaN), titanium (Ti), titanium nitride (TiN), titanium silicon nitride (TiSiN) and tungsten nitride (WN), or a combination layer thereof.

42. The method according to claim 28, wherein forming the metal combination layer includes: forming a barrier metal layer conformally covering insides of the first and second trenches;
forming a lower seed layer conformally covering insides of the first and second trenches;
forming a lower copper layer completely filling the first trench and conformally covering the inside of the second trench;
forming an additive material layer on the substrate having the lower copper layer, a bottom surface of the additive material layer being lower than a top surface of the dielectric;
forming an upper seed layer on the substrate having the additive material layer; and
forming an upper copper layer on the substrate having the upper seed layer.

43. The method according to claim 28, wherein planarizing the metal combination layer is performed using a chemical mechanical polishing (CMP) process employing the dielectric as a stop layer.

44. The method according to claim 28, wherein the annealing is performed at a temperature of about 250° C. to 450° C.

45. The method according to claim 28, wherein the annealing is performed at a temperature of about 150° C. to 230° C.

46. A method of forming an interconnection in a semiconductor device, comprising:
forming a dielectric on a substrate;
forming a first trench, a second trench having a larger width than the first trench, and a contact hole penetrating the dielectric downward on a bottom surface of the second trench, in the dielectric; and
forming a first interconnection in the first trench, a contact plug in the contact hole, and a second interconnection in the second trench,
wherein the first interconnection includes a first pure copper pattern, and the second interconnection includes a copper alloy pattern.

47. The method according to claim 46, wherein forming the first interconnection, the contact plug, and the second interconnection comprises:
forming a metal combination layer filling the first trench, the contact hole, and the second trench and covering a top surface of the substrate;
planarizing the metal combination layer and forming the first interconnection, the contact plug, and a preliminary interconnection in the second trench; and
annealing the preliminary interconnection and forming the second interconnection.

48. The method according to claim 47, wherein forming the metal combination layer comprises:
forming a lower copper layer completely filling the first trench and the contact hole and conformally covering the inside of the second trench; and
forming an additive material layer on the substrate having the lower copper layer, a bottom surface of the additive material layer being lower than a top surface of the dielectric.

49. The method according to claim 47, wherein forming the metal combination layer includes:
forming a barrier metal layer conformally covering insides of the first trench, the contact hole and the second trench;
forming a lower seed layer conformally covering insides of the first trench, the contact hole and the second trench;
forming a lower copper layer completely filling the first trench and the contact hole and conformally covering the inside of the second trench;
forming an additive material layer on the substrate having the lower copper layer, a bottom surface of the additive material layer being lower than a top surface of the dielectric;
forming an upper seed layer on the substrate having the additive material layer; and
forming an upper copper layer on the substrate having the upper seed layer.

50. The method according to claim 47, wherein forming the metal combination layer includes:
forming a barrier metal layer conformally covering insides of the first trench, the contact hole and the second trench;
forming a lower seed layer conformally covering insides of the first trench, the contact hole and the second trench;
forming a lower copper layer completely filling the first trench and the contact hole and conformally covering the inside of the second trench;
forming an additive material layer on the substrate having the lower copper layer, a bottom surface of the additive material layer being lower than a top surface of the dielectric;
forming an upper barrier metal layer on the substrate having the additive material layer, a bottom surface of the upper barrier metal layer being lower than a top surface of the dielectric;
forming an upper seed layer on the substrate having the upper barrier metal layer; and
forming an upper copper layer on the substrate having the upper seed layer.

51. The method according to claim 47, wherein forming the metal combination layer includes:
forming a barrier metal layer conformally covering insides of the first trench, the contact hole and the second trench;
forming a lower seed layer conformally covering insides of the first trench, the contact hole and the second trench;
forming a lower copper layer completely filling the first trench and the contact hole and conformally covering the inside of the second trench;
forming an intermediate barrier metal layer on the substrate having the lower copper layer;
forming an additive material layer on the substrate having the intermediate barrier metal layer, a bottom surface of the additive material layer being lower than a top surface of the dielectric;
forming an upper seed layer on the substrate having the additive material layer, a bottom surface of the upper seed layer being lower than a top surface of the dielectric; and
forming an upper copper layer on the substrate having the upper seed layer.

52. The method according to claim 47, wherein planarizing the metal combination layer is performed using a chemical mechanical polishing (CMP) process of employing the dielectric as a stop layer.

53. The method according to claim 47, wherein the annealing is performed at a temperature of about 250° C. to 450° C.

54. The method according to claim 47, wherein the annealing is performed at a temperature of about 150° C. to 230° C.

55. The method according to claim 47, further comprising:
during the annealing of the preliminary interconnection, transforming the contact plug to a copper alloy plug,
wherein the copper alloy plug has the copper alloy pattern.

56. The method according to claim 46, wherein the first interconnection is formed of a first barrier metal pattern and the first pure copper pattern which are sequentially stacked, and the contact plug is formed of a second barrier metal pattern and the second pure copper pattern which are sequentially stacked.

57. The method according to claim 56, further comprising:
forming a first lower seed pattern between the first barrier metal pattern and the first pure copper pattern; and
forming a second lower seed pattern between the second barrier metal pattern and the second pure copper pattern.

58. The method according to claim 46, further comprising:
forming a second contact hole penetrating the dielectric downward on a bottom surface of the first trench.

59. The method according to claim 58, further comprising:
forming a second contact plug in the second contact hole,
wherein the second contact plug has the first pure copper pattern.
